(19) United States
(12) Patent Application Publication
(10) Pub. No.: US 2019/0369433 A1
(43) Pub. Date: Dec. 5, 2019

(54) CIRCUIT BOARD AND MANUFACTURING METHOD THEREOF

(71) Applicants: HKC CORPORATION LIMITED, SHUITIAN VILLAGE, SHIYAN SUB (CN); CHONGQING HKC OPTOELECTRONICS TECHNOLOGY CO.,LTD., CHONGQING (CN)

(72) Inventor: YU-JEN CHEN, CHONGQING (CN)

(21) Appl. No.: 16/481,457

(22) PCT Filed: Sep. 11, 2017
(86) PCT No.: PCT/CN2017/101173

§ 371 Date: Jul. 29, 2019

(30) Foreign Application Priority Data
Jul. 6, 2017 (CN) 201710546295.6

(51) Int. Cl. G02F 1/1343; H05K 1/11; H05K 1/18; H05K 3/46; H05K 3/40

(52) U.S. Cl. CPC G02F 1/13439; H05K 1/116; H05K 1/181; H05K 2201/10136; H05K 3/4038; H05K 2201/10015; H05K 3/4644

(57) ABSTRACT

Disclosed a circuit board and a manufacturing method thereof, the circuit board comprises a substrate and a bridge circuit disposed on the substrate, wherein the bridge circuit comprises a first metal layer and a second metal layer, and a projected intersecting portion of the first metal layer and the second metal layer is penetrated and coupled to a bridge metal.

### CROSS-REFERENCE TO RELATED APPLICATION

This application claims the benefit of China Patent Application No. 2017105462956, filed on Jul. 6, 2017, in the State Intellectual Property Office of the People's Republic of China, the disclosure of which is incorporated herein in its entirety by reference.

### BACKGROUND OF THE INVENTION

### 1. Field of the Invention

The present application involves to the field of display technology, in particular it involves to a circuit board and a manufacturing method thereof.

### 2. Description of the Related Art

With the development and progress of science and technology, the liquid crystal display devices have become the mainstream display products and been widely used due to it has the advantages of thin body, low power consumption, and low radiation. Most of the commercially available liquid crystal displays are backlight type liquid crystal displays each including a liquid crystal panel and a backlight module. The working principle of the liquid crystal panel is that the liquid crystal molecules are disposed between and then the driving voltages are applied to the two parallel transparent electrodes to control the rotational direction of the liquid crystal molecules so as to refract light from the backlight module to produce the screen image.

The thin film transistor-liquid crystal displays (TFT-LCD) have gradually occupied the dominant position in the field of display since they exhibit the performances such as low power consumption, excellent image quality, higher production yield, etc. Similarly, the thin film transistor-liquid crystal display comprises a liquid crystal panel and a backlight module, the liquid crystal panel comprises a color filter (CF) substrate, a thin film transistor array substrate and a mask, and a transparent electrode is disposed at each of the two opposing inner sides of the above substrate. One liquid crystal (LC) layer is disposed between the two substrates.

It has become important to develop the thin film transistor-liquid crystal display (TFT-LCD) having narrow frames or frameless, it is capable to enhance the overall appearance of the real images and in particular to reduce manufacturing costs as pursued by one skilled in the art when realizing the narrow frame or frameless.

In the narrow frame and frameless product design, the gate terminal high-density integrated circuit has designed as the gate driver less (GDL) circuit, its design is a important mean of reducing the integrated circuit cost. However, when the resolution is getting higher and higher, how to reduce the effective space of the gate terminal high-density integrated circuit also leads to another problem, that is, how to further improve the utilization area of the relevant circuit becomes an urgent problem to be solved by one skilled in the art.

It should be noted that the above description of the Related Art is only intended to facilitate the clear and complete description of the technical solutions of the present application and to facilitate understanding for one skilled in the art. Although the technical solutions are described in the Related Art of the present application, those technical solutions should not to be construed as well known to one skilled in the art.

### SUMMARY OF THE INVENTION

In view of the aforementioned defects of the conventional art, the technical mean of the present application is to provide a circuit board capable of improving the space utilization and a method of manufacturing the same.

In order to realize the above object, the present application provides a circuit board, comprising:

a substrate; and
a bridge circuit disposed on the substrate;
wherein the bridge circuit comprises a first metal layer and a second metal layer,
wherein a projected intersecting portion of the first metal layer and the second metal layer is penetrated and coupled to a bridge metal.

The present application further disposes a method for manufacturing any one of the circuit boards described herein, comprising:

forming a first metal layer metal layer and a second metal layer of a bridge circuit respectively in a circuit board; and
penetrating a projected intersecting portion of the first metal layer and the second metal layer, and coupling the first metal layer and the second metal layer to a bridge metal;
wherein the bridge circuit is constituted of the first metal layer, the second metal layer and the bridge metal.

For the conventional gate terminal high-density integrated circuit, in particular the bridge circuit, the first metal layer and the second metal layer on the different pattern layers are bridged together via the two through holes in cooperation with the first transparent electrode, but the bridge point occupies the areas of the two contact through holes in the existing multi-stage series structure, it takes up too much space, and thus low space utilization. In the present application, the projected intersecting portion of the first metal layer and the second metal layer is penetrated and coupled to a bridge metal instead of the configuration structures where the two through holes and the first transparent electrode are disposed to communicate the first metal layer and the second metal layer. As such, the improved area by the present application is only about half of the existing area to improve the space utilization while achieving the original bridging object, it is advantageous to make the narrower frame. Furthermore, the first metal layer and the second metal layer but not the first transparent electrode are used in the peripheral GDL circuit for bridging, thereby effectively reducing the poor contact problem caused by the through holes.

The specific embodiments of the present application have been disclosed in detail with reference to the following description and the accompanying drawings, wherein the methods of employing the principles of the present application are specified. It should be understood that the embodiments of the present application are not thus limited in scope. Any modification, change and equivalent replacement may be made the embodiments of the present application without departing from the scope and the spirit of the present application and is covered by the appended claims.

The features described and/or illustrated for an embodiment may be used in one or more other embodiments in the same or similar manner for example, those features may be in combination with or used to alternate the features in other embodiments.

It should be emphasized that the term “comprise/include” as used herein refers to the presence of the features, components, steps or elements, but not refers to preclude the presence or addition of one or more other features, components, steps or elements.

### BRIEF DESCRIPTION OF THE DRAWINGS

For a better understanding of the embodiments of the present application, the accompanying drawings are provided for exemplifying the embodiments of the present application and setting forth the principles of the present application together with the description. It is apparent that the accompanying drawings described below only illustrate the some embodiments of the present application, and one skilled in the art can further obtain other drawings in accordance with those accompanying drawings without paying inventive labor. The accompanying drawings of the present application:

FIG. 1 is a schematic diagram illustrating a circuit board having a through hole;

FIG. 2 is an enlarged schematic diagram illustrating a bridge part of a circuit board shown in FIG. 1;

FIG. 3 is a schematic diagram illustrating a circuit board according to an embodiment of the present application;

FIG. 4 is a schematic diagram illustrating one capacitor area and another capacitor having a through hole according to a comparative example;

FIG. 5 is a schematic diagram illustrating one capacitor area and another capacitor having a through hole according to an embodiment of the present application;

FIG. 6 is a flowchart of a method for manufacturing circuit board according to an embodiment of the present application.

### DETAILED DESCRIPTION OF THE PREFERRED EMBODIMENTS

To make one skilled in the art better understanding of the technical solutions of the present application, the technical solutions in the embodiments of the present application will be described clearly and fully with reference to the accompanying drawings described in the embodiments of the present application. It is obvious that the described embodiments are just a part but not all of the embodiments of the present application. One skilled in the art can obtain other embodiments based on the embodiments of the present application without any inventive work and all those embodiments should be covered by the appended claims.

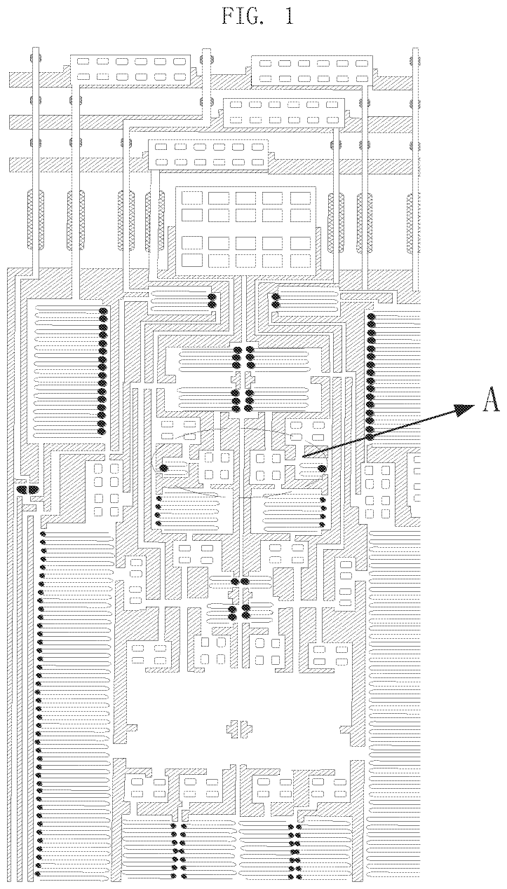

FIG. 1 is a schematic diagram illustrating a circuit board having a through hole, wherein the through hole passes through the circuit board and the bridge part A of the circuit board is shown in the elliptic circle encircled, there are always problems of applying the required circuit design for these and other circuits at the same design value under the condition of the limited space and area.

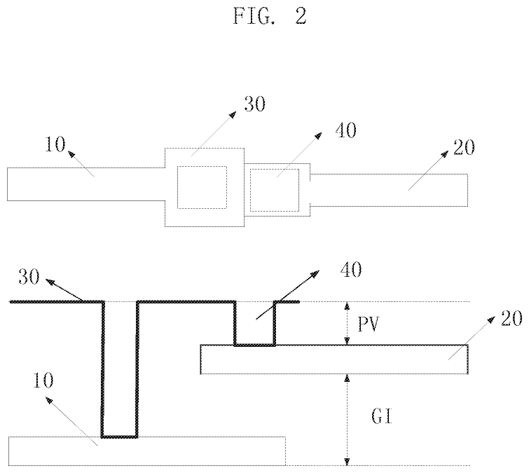

FIG. 2 is an enlarged schematic diagram illustrating a bridge part of a circuit board shown in FIG. 1. The bridge part made of the two through holes and the transparent electrode in the traditional process may not be satisfied with the narrow frame required for the high-density circuit used for the ultra-high resolution display. The first layer metal 10 shown in FIG. 2 corresponds to the first metal layer of the present application, the second metal layer 20 shown in FIG. 2 corresponds to the second metal layer 20 of the present application, the through hole 40 shown in FIG. 2 corresponds to the through hole (or called as a via hole or a contact hole). Furthermore, the passivation layer PV corresponds to the distance between the upper surface of the first metal layer and the upper surface of the circuit board, the insulating layer GI corresponds to the distance between the lower surface of the first metal layer and the lower surface of the circuit board. The transparent electrode may be made of an indium tin oxide (ITO) material.

Refer to FIG. 1 and FIG. 2, it can be seen that the two thought holes (or called as contact holes) are required for the existing bridge part, those holes occupy the areas of the display panel and thus it is difficult to satisfy the requirement in the pursuit of having the narrow frame, even frameless, for the display panel.

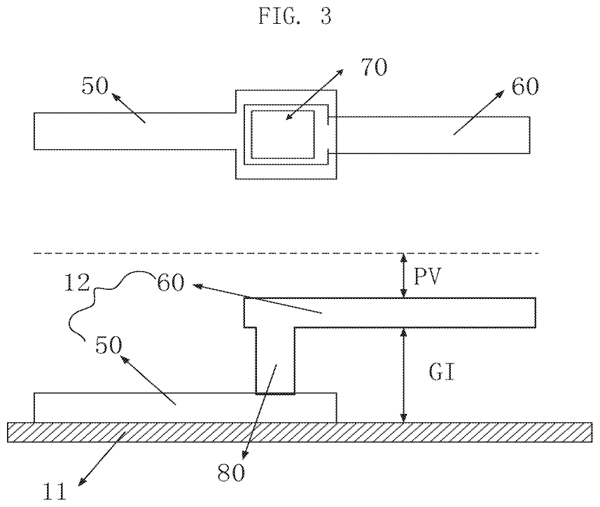

FIG. 3 is a schematic diagram illustrating a circuit board according to an embodiment of the present application, wherein the schematic diagram of the circuit is shown in the upper part of FIG. 3, the cross section diagram corresponding to the circuit diagram is shown in the lower part of FIG. 3, referring to FIG. 2, the circuit board comprises: a substrate 11 and a bridge circuit 12 disposed on the substrate 11, wherein the bridge circuit comprises a first metal layer 50 and a second metal layer 60, and a projected intersecting portion of the first metal layer 50 and the second metal layer 60 is penetrated and coupled to the bridge metal 80.

For the conventional gate terminal high-density integrated circuit, in particular the bridge circuit, the first metal layer and the second metal layer on the different pattern layers are bridged together via the two through holes in cooperation with the first transparent electrode, but the bridge point occupies the areas of the two contact through holes in the existing multi-stage series structure, it takes up too much space, and thus low space utilization. In the present application, the projected intersecting portion of the first metal layer and the second metal layer is penetrated and coupled to the bridge metal instead of the configuration structures where the two through holes and the first transparent electrode are disposed to communicate the first metal layer and the second metal layer. As such, the improved area by the present application is only about half of the existing area to improve the space utilization while achieving the original bridging object, it is advantageous to make the narrower frame. Furthermore, the first metal layer and the second metal layer but not the first transparent electrode are used in the peripheral GDL circuit for bridging, thereby effectively reducing the poor contact problem caused by the through holes.

In the embodiment, the bridge metal 80 may be an extension part of the second metal layer 60 or a connecting member, wherein the connecting member is independent from the second metal layer 60.

The distance between the lower surface of the first metal layer 50 and the upper surface of the circuit board is smaller than the distance between the lower surface of the first metal layer 50 and the lower surface of the second metal layer 60. In the solution, the original design value of the capacitance value to be considered is retained, but the capacitance architecture is changed by the bridge metal, such that the smaller space only need to be remained since the distance between the lower surface of the first metal layer and the upper surface of the circuit board is smaller than the distance between the lower surface of the first metal layer and the lower surface of the second metal layer according to the formula of the capacitor, thereby further increasing the spatial utilization of the solution.

In the embodiment, the distance between the lower surface of the first metal layer 50 and the upper surface of the circuit board is half the distance between the lower surface of the first metal layer 50 and the lower surface of the second metal layer 60. In the solution, the original design value of the capacitance value to be considered is retained, but the capacitance architecture is changed by the bridge metal, such that the smaller space only needs to be remained since the distance between the lower surface of the first metal layer and the upper surface of the circuit board is smaller than the distance between the lower surface of the first metal layer and the lower surface of the second metal layer, according to the formula of the capacitor represented by C=εS/4πkd, wherein ε is a constant, S is an area of a front surface of the capacitor, d is a distance between the capacitive plates, k is a electrostatic force constant. The common parallel-plate capacitor has a capacitor represented by C=εS/d, wherein ε is a permittivity of the intervene material of the plate, S is an area of the plate, d is a distance between the plates. It can be seen that the half space only needs to be remained under the condition of the same capacitor according to the formula of the capacitor, thereby further increasing the spatial utilization of the solution.

In the embodiment, the projected intersecting portion of the first metal layer 50 and the second metal layer 60 is communicated via the through hole 70, the bridge metal 80 is disposed in the through hole 70 and coupled to the first metal layer 50 and the second metal layer 60. In the solution, it can ensure connectivity by disposing the bridge metal in the through hole.

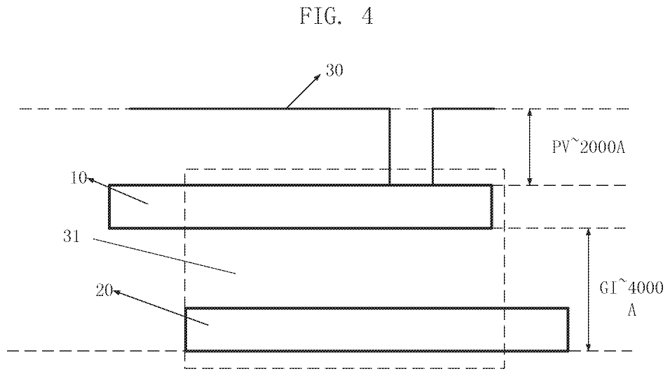

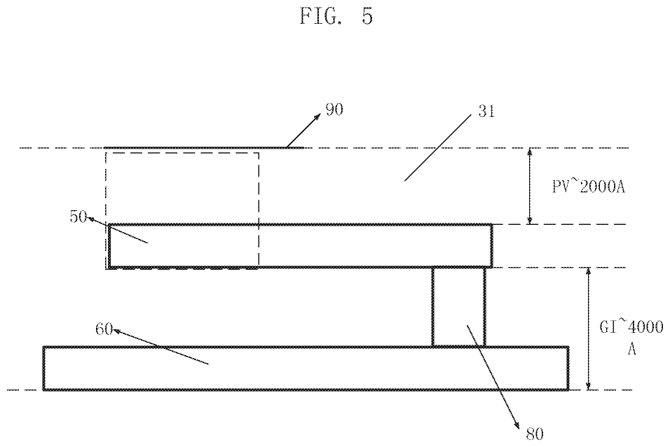

Refer to FIGS. 2 to 5, it can be seen that the thickness of the passivation layer is a distance between the upper surface of the first metal layer and the upper surface of the circuit board and may be 2000 Å, and the thickness of the insulating layer is a distance between the lower surface of the first metal layer and the lower surface of the circuit board and may be 4000 Å. In the embodiment, the second transparent electrode 30 is disposed on the upper surface of the circuit board and corresponds to a portion of the projected intersecting portion of the first metal layer 50 and the second metal layer 60.

The first transparent electrode 90 is disposed at a preset distance away from the periphery of the through hole 70. In the solution, the transparent electrodes disposed in the positions other than the periphery of the through holes are remained such that the circuits disposed in these positions are unimpeded, the bridge metal is disposed in the through hole and the periphery of the through hole to ensure coupling, and the transparent electrode is related to the required capacitor region 31. Here, it is possible to appropriately reduce the area of the transparent electrode of the projected intersecting portion while maintaining the same capacitance adjustment, thereby increasing the space utilization without worrying that the formed capacitor region 31 is too large.

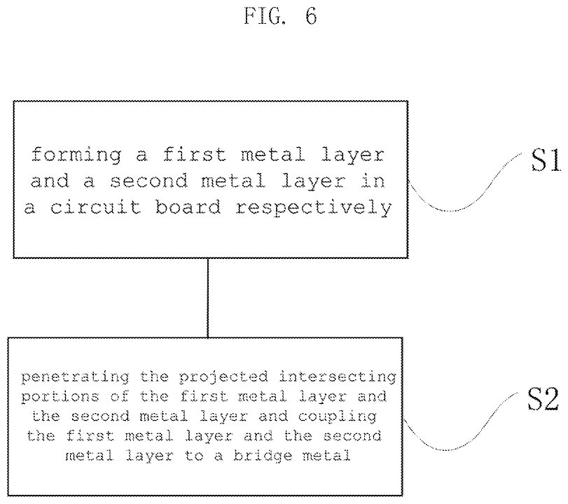

FIG. 6 is a flowchart of a method for manufacturing circuit board according to an embodiment of the present application. Refer to FIGS. 2 to 6, it can be seen that the present application also discloses a method for manufacturing any of the circuit boards described herein, the method comprises:

S1: forming a first metal layer 50 and a second metal layer 60;
S2: penetrating the projected intersecting portion of the first metal layer 50 and the second metal layer 60, and coupling the first metal layer 50 and the second metal layer 60 to a bridge metal 80.
The first metal layer 50, the second metal layer 60 and the bridge metal 80 constitutes the bridge circuit of the circuit board. For the conventional gate terminal high-density integrated circuit, in particular the bridge circuit, the first metal layer 50 and the second metal layer 60 on the different pattern layers are bridged together via the two through holes 70 in cooperation with the first transparent electrode 90, but the bridge point occupies the areas of the two contact through holes 70 in the existing multi-stage series structure, it takes up too much space, and thus low space utilization. In the present application, in the gate terminal high-density integrated circuit manufactured by the method, the projected intersecting portion of the first metal layer 50 and the second metal layer 60 is penetrated and coupled to the bridge metal 80 instead of the configuration structures where the two through holes 70 and the first transparent electrode 90 are disposed to communicate the first metal layer 50 and the second metal layer 60. As such, As such, the improved area by the present application is only about half of the existing area to improve the space utilization while achieving the original bridging object, it is advantageous to make the narrower frame. Furthermore, the first metal layer and the second metal layer but not the first transparent electrode are used in the peripheral GDL circuit for bridging, thereby effectively reducing the poor contact problem caused by the through holes.

In the embodiment, the bridge metal 80 may be an extension part of the second metal layer 60 or a connecting member, wherein the connecting member is independent from the second metal layer 60.

The distance between the lower surface of the first metal layer 50 and the upper surface of the circuit board is smaller than the distance between the lower surface of the first metal layer 50 and the lower surface of the second metal layer 60 when forming the first metal layer 50 and the second metal layer 60. In the solution, the original design value of the capacitance value to be considered is retained, but the capacitance architecture is changed by the bridge metal 80, such that the smaller space only needs to be remained since the distance between the lower surface of the first metal layer 50 and the upper surface of the circuit board is smaller than the distance between the lower surface of the first metal layer 50 and the lower surface of the second metal layer 60 according to the formula of the capacitor, thereby further increasing the spatial utilization of the solution.

In the embodiment, the first metal layer 50 and the second metal layer 60 are formed such that the distance between upper surface of the first metal layer 50 and the upper surface of the circuit board is smaller than or equal to half the distance between the lower surface of the first metal layer 50 and the lower surface of the second metal layer 60. In the solution, the original design value of the capacitance value to be considered is retained, but the capacitance architecture is changed by the bridge metal 80, thus it can be seen that the half space only needs to be remained since the distance between the lower surface of the first metal layer 50 and the upper surface of the circuit board is smaller than the distance between the lower surface of the first metal layer 50 and the lower surface of the second metal layer 60 according to the formula of the capacitor, thereby further increasing the spatial utilization of the solution.

The through hole is formed for communicating the projected intersecting portion of the first metal layer 50 and the second metal layer 60.

The bridge metal 80 is formed in the through hole and coupled to the first metal layer 50 and the second metal layer 60. In the solution, it can ensure connectivity by disposing the bridge metal 80 in the through hole.

In the embodiment, the first transparent electrode 90 is disposed on the upper surface of the circuit board and corresponds to a portion of the projected intersecting portion of the first metal layer 50 and the second metal layer 60.

The formed first transparent electrode 90 is disposed at a preset distance away from the periphery of the through hole. In this solution, the transparent electrodes 90 disposed in the positions other than the periphery of the through hole are remained such that the circuits disposed in these positions are unimpeded, the bridge metal 80 is disposed in the through hole and the periphery of the through hole to ensure coupling, and the first transparent electrode 90 is related to the required capacitor. Here, it is possible to appropriately reduce the area of the transparent electrode 90 of the projected intersecting portion while maintaining the same capacitance adjustment, thereby increasing the space utilization without worrying that the formed capacitor is too large.

The circuit board of the present application may be suitable for the electrical device and may be a display panel, but not limited thereto.

The above display panel comprises a liquid crystal display panel, an organic light emitting diode (OLED) display panel, a quantum dot light emitting diode (QLED) display panel, a plasma display panel, a flat panel, a curved-surface display panel, etc. It is possible to reduce the space occupied by the gate terminal, improve the space utilization, and facilitate the realization of the technology such as the narrow frame by applying the circuit board of the present application. Of course, the circuit board may also be applied to other similar circuits such that the more circuits disposed in the limited space to realize more functions, it is advantageous to improve the functions of the display device.

The preferred embodiments of the present application are described in detail above. It should be understood that one skilled in the art can make many modifications and variations in accordance with the teachings of the present application without paying inventive labor. Therefore, all of the technical solutions can be obtained with logical analysis, deduction, or limited experimentation by one skilled in the art and should be covered by the appended claims.

What is claimed is:

1. A circuit board, comprising:
a substrate; and
a bridge circuit disposed on the substrate;
wherein the bridge circuit comprises a first metal layer and a second metal layer,
wherein a projected intersecting portion of the first metal layer and the second metal layer is penetrated and coupled to a bridge metal.

2. The circuit board of claim 1, wherein the bridge metal is an extension part of the second metal layer or a connecting member, wherein the connecting member is independent from the second metal layer; and
a distance between a lower surface of the first metal layer and a upper surface of the circuit board is smaller than a distance between a lower surface of the first metal layer and a lower surface of the second metal layer.

3. The circuit board of claim 2, wherein the distance between the lower surface of first metal layer and the upper surface of the circuit board is equal to half the distance between the lower surface of the first metal layer and the lower surface of the second metal layer.

4. The circuit board of claim 1, wherein the bridge metal is an extension part of the second metal layer or a connecting member, wherein the connecting member is independent from the second metal layer;
a distance between a lower surface of the first metal layer and a upper surface of the circuit board is smaller than a distance between a lower surface of the first metal layer and a lower surface of the second metal layer; and
a distance between the lower surface of first metal layer and the upper surface of the circuit board is equal to half a distance between the lower surface of the first metal layer and the lower surface of the second metal layer.

5. The circuit board of claim 1, wherein the projected intersecting portion of the first metal layer and the second metal layer is communicated to each other via a through hole, the bridge metal is disposed in the through hole and coupled to the first metal layer and the second metal layer.

6. The circuit board of claim 5, wherein a first transparent electrode is disposed on a upper surface of the circuit board and corresponds to a portion of the projected intersecting portion of the first metal layer and the second metal layer; and
the first transparent electrode is disposed at a preset distance away from the periphery of the through hole.

7. The circuit board of claim 1, wherein the projected intersecting portion of the first metal layer and the second metal layer is communicated to each other via a through hole, the bridge metal is disposed in the through hole and coupled to the first metal layer and the second metal layer; and
a first transparent electrode is disposed on a upper surface of the circuit board and corresponds to a portion of the projected intersecting portion of the first metal layer and the second metal layer, the first transparent electrode is disposed at a preset distance away from the periphery of the through hole.

8. A circuit board, comprising:
a substrate; and
a bridge circuit disposed on the substrate;
the bridge circuit comprises a first metal layer and a second metal layer;
a projected intersecting portion of the first metal layer and the second metal layer is penetrated and coupled to a bridge metal;
the bridge metal is an extension part of the second metal layer or a connecting member wherein the connecting member is independent from the second metal layer; a distance between a lower surface of the first metal layer and a upper surface of the circuit board is smaller than a distance between a lower surface of the first metal layer and a lower surface of the second metal layer;
the distance between the lower surface of first metal layer and the upper surface of the circuit board is equal to half the distance between the lower surface of the first metal layer and the lower surface of the second metal layer;
the projected intersecting portion of the first metal layer and the second metal layer is communicated to each other via a through hole, the bridge metal is disposed in the through hole and coupled to the first metal layer and the second metal layer; and
a first transparent electrode disposed on the upper surface of the circuit board and corresponding to a portion of the projected intersecting portion of the first metal layer and the second metal layer, the first transparent electrode is disposed at a preset distance away from the periphery of the through hole.

9. A method for manufacturing circuit board, comprising:
forming a first metal layer metal layer and a second metal layer of a bridge circuit respectively in a circuit board;
penetrating a projected intersecting portion of the first metal layer and the second metal layer; and
coupling the first metal layer and the second metal layer to a bridge metal;
wherein the bridge circuit is constituted of the first metal layer, the second metal layer and the bridge metal.

10. The manufacturing method of claim 9, wherein the bridge metal is an extension part of the second metal layer or a connecting member, wherein the connecting member is independent from the second metal layer; and
forming a distance between a lower surface of the first metal layer and a upper surface of the circuit board is smaller than a distance between a lower surface of the first metal layer and a lower surface of the second metal layer in the step of forming the first metal layer and the second metal layer.

11. The manufacturing method of claim 10, wherein the step of forming the first metal layer and the second metal layer comprises forming the distance between the upper surface of the first metal layer and the upper surface of the circuit board smaller than or equal to half the distance between the lower surface of the first metal layer and the lower surface of the second metal layer.

12. The manufacturing method of claim 9, wherein the bridge metal is an extension part of the second metal layer or a connecting member, wherein the connecting member is independent from the second metal layer;
a distance between a lower surface of the first metal layer and a upper surface of the circuit board is smaller than a distance between a lower surface of the first metal layer and a lower surface of the second metal layer in the step of forming the first metal layer and the second metal layer; and
the distance between the upper surface of first metal layer and the upper surface of the circuit board is smaller than or equal to half the distance between the lower surface of the first metal layer and the lower surface of the second metal layer in the step of forming the first metal layer and the second metal layer.

13. The manufacturing method of claim 9, further comprising forming a through hole for communicating the projected intersecting portion of the first metal layer and the second metal layer to each other; and
forming the bridge metal in the through hole, and coupling the bridge metal to the first metal layer and the second metal layer.

14. The manufacturing method of claim 13, further comprising forming a first transparent electrode on a upper surface of the circuit board, wherein the first transparent electrode corresponds to a portion of the projected intersecting portion of the first metal layer and the second metal layer; and
forming the first transparent electrode at a preset distance away from the periphery of the through hole.

15. The manufacturing method of claim 9, further comprising forming a through hole for communicating the projected intersecting portion of the first metal layer and the second metal layer to each other;
forming the bridge metal in the through hole, and coupling the bridge metal to the first metal layer and the second metal layer; and
forming a first transparent electrode on a upper surface of the circuit board, wherein the first transparent electrode corresponds to a portion of the projected intersecting portion of the first metal layer and the second metal layer.
